(19) United States
(12) Patent Application Publication
(10) Pub. No.: US 2023/0014921 A1
(43) Pub. Date: Jan. 19, 2023

(54) CARD FASTENERS

(71) Applicant: Hewlett-Packard Development Company, L.P., Spring, TX (US)

(72) Inventor: Tien Liang Chung, Taipei City (TW)

(73) Assignee: Hewlett-Packard Development Company, L.P., Spring, TX (US)

(21) Appl. No.: 17/786,612

(22) PCT Filed: Dec. 20, 2019
(86) PCT No.: PCT/US2019/068096

§ 371 Date: Jun. 17, 2022

(51) Int. Cl. H01R 13/639; H05K 1/18

(52) U.S. Cl. CPC H01R 13/639; H05K 1/18; H01R 12/737

(57) ABSTRACT

Examples of card fasteners and assemblies for fastening cards to printed circuit boards are discussed. A card fastener comprises a frame comprising a first arm, a second arm, and an intermediate portion joining the first arm and the second arm. A compressive pad is attached to the intermediate portion. The first arm and second arm are to couple to hooks on a printed circuit board of a device and the compressive pad is to come in contact with the card.

### BACKGROUND

Various installable components, for example, expansion or add-on cards, may be used for enhancing the capabilities of computing devices. Examples of such add-on cards may include memory, processing components, additional sound cards, and enhanced graphics cards, among others. The cards may be connected to a printed circuit board (PCB) using designated slots. For example, one side of the card may connect to a slot, which forms electrical connections with the PCB. Another side may be connected to a device chassis, such as a cover of a computing device, via a holder that may be fixed onto the card and the chassis.

### BRIEF DESCRIPTION OF DRAWINGS

The following detailed description references the figures, wherein:

FIG. 1 illustrates an example assembly of a card fastened on a PCB, according to an example implementation of the present subject matter;

FIG. 2A illustrates an example card fastener for fastening a card to a PCB, according to an example implementation of the present subject matter;

FIG. 2B illustrates an exploded view of the card fastener of FIG. 2A, according to an example implementation of the present subject matter;

FIG. 3 illustrates an enlarged view of an example card fastener coupled to a hook on a PCB, according to an example implementation of the present subject matter;

FIG. 4 illustrates another example assembly of a card fastened on a PCB, according to an example implementation of the present subject matter; and

FIG. 5 illustrates an example printed circuit board with hooks for fastening a card, according to an example implementation of the present subject matter.

### DETAILED DESCRIPTION

Add-on cards or expansion cards for computing devices, such as desktop computers, notebook computers, and gaming systems, provide them with increased capabilities. Examples of expansion cards may be a memory card, a graphics card, a sound card, and the like. A card may be connected to a slot on a PCB on one side of the card. An adjacent side of the card may be coupled to a device chassis, such as a cover of the computing device. For coupling the card to the device chassis, a holder may be provided on the card on the side to be coupled to the device chassis and may be connected to the device chassis using, for example, screws. When the card is connected to the PCB on one side and the adjacent side is connected to the device chassis, the other sides generally remain free and may be affected by vibrations.

An example of an add-on card is a graphics card, which provides enhanced graphics capabilities to a computing device, for example in high-end gaming systems. The graphics card may either occupy one slot or, in cases where the graphics card is large, may even occupy two slots on a PCB. Some graphics cards may be several inches long. In an example, cards may be about 12 inches long. A first side of the graphics card may be connected to a PCB slot and a second side, adjacent to the first side, may be attached to a device chassis using a holder mounted on the chassis and on the second side of the card.

When the graphics card is long, for example more than 7 inches, or when the card occupies two slots, the free sides of the card may vibrate or may get disconnected from the PCB during transport or shipping of the device. As a result, additional holders may be mounted on the device chassis and the card to hold the card in place. This makes it difficult to assemble or disassemble the cards, for example, in a production line, increasing product throughput time and leading to increased costs.

Aspects of the present subject matter relate to a card fastener, and fastening cards onto PCBs of a computing device, for example, fastening add-on or expansion cards to a motherboard of a device. The device may include desktop computing devices, notebook computers, gaming systems, workstations, and the like. Although the following description is described with respect to a device motherboard, cards may be fastened to any PCB, and the specific description and examples should not be construed as limitations.

In an example, an assembly may include a card connected to a device circuit board, for example, motherboard. The device motherboard may be provided with a plurality of hooks attached to the motherboard, and a card fastener may be removably disposed on the card and coupled to the plurality of hooks. The card fastener comprises a first end portion that removably couples with the plurality of hooks on the motherboard to securely fasten the card to the motherboard. The card fastener includes a compressive pad on a second end portion, wherein the compressive pad comes in contact with the card. The card fastener may be made of spring wires in one example.

In one example, the card fastener comprises a holding portion. Manually deforming the holding portion allows the card fastener to be slid into position for the first end portion to engage with the plurality of hooks on the motherboard upon releasing the holding portion. When the card fastener is coupled to the hooks, manually deforming the holding portion allows the card fastener to disengage from the hooks and be removed.

In an example, a plurality of hooks may be attached to the device motherboard to fasten the card to the motherboard. In an example, the hooks may have a substantially U-shape and may be soldered onto the motherboard.

In another example, the card fastener comprises a frame with a first arm and a second arm and an intermediate portion joining the first arm and the second arm. The frame is substantially U-shaped, and the intermediate portion forms the base of the U-shape and the first and second arms form the arms of the U-shape. The compressive pad, which is to come in contact with the card connected to the motherboard, is attached to the intermediate portion of the frame. The free ends of the first arm and the second arm comprise a prong with a protrusion to couple to the hooks attached to the motherboard.

Thus, the present subject matter provides for fastening cards to a device motherboard in a simple and inexpensive manner. The card fasteners may be easily attached to or detached from the card and the device motherboard without using tools, such as screws and screwdrivers. This allows for easy assembly and disassembly of the card fasteners, for example, during production or during transport of the device. Fastening the card using aspects of the present subject matter prevents the cards from vibrating or disengaging from the slots. This ensures that production lines function efficiently and the device functions properly after transport.

Furthermore, since a plurality of hooks may be placed on the motherboard in a direction along the length of the card, cards of varying length may be easily accommodated without having to change the design of the holders that connect the card to the device chassis. In addition, cards of different lengths or widths may be fastened with chassis of different designs without changing holder designs to correspond to the chassis design. This makes production simple, efficient, and inexpensive. In various examples, the card fasteners may be removed after production or transport, and may be reused, further saving costs.

The following description refers to the accompanying drawings. Wherever possible, the same reference numbers are used in the drawings and the following description to refer to the same or similar parts. While several examples are described in the description, modifications, adaptations, and other implementations are possible. Accordingly, the following detailed description does not limit the disclosed examples. Instead, the proper scope of the disclosed examples may be defined by the appended claims.

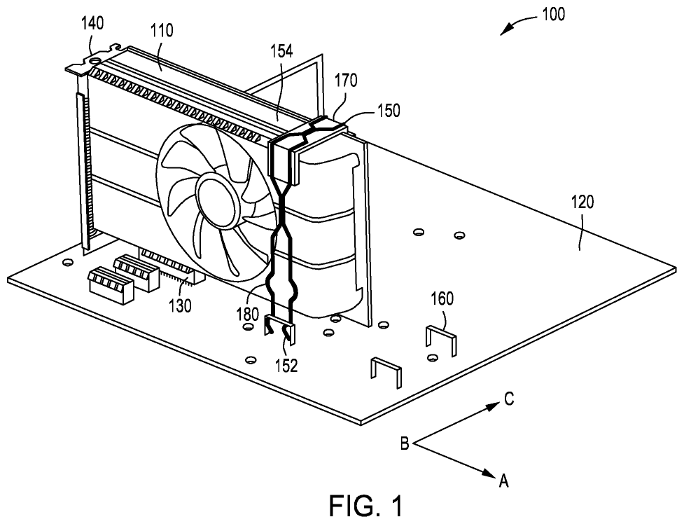

FIG. 1 illustrates an example assembly 100 of a card fastened on a PCB, according to an example implementation of the present subject matter. The assembly 100 may comprise a card 110 connected to a device motherboard 120. The card 110 may be an add-on or expansion card, such as a graphics card, a memory card, or an audio card. In various examples, the device may be a desktop computer, a gaming system, a workstation, and the like. The card 110 may be connected to the motherboard 120 via a slot 130 disposed on the motherboard 120. A first side of the card 110 may be connected to the slot 130. A holder 140 may be attached to the card 110 on one side of the card 110, for attaching to the device chassis. In an example, the device chassis may be a housing or a cover of the computing device. In an example, the holder 140 may be attached to the card 110 on a second side of the card 110 that is adjacent to the first side.

A card fastener 150 may be disposed on a third side of the card 110, the third side being opposite to the first side. The card fastener 150 may be disposed closer to a fourth side of the card 110, which is opposite the second side, than to the second side of the card 110. In an example, the card fastener 150 may be disposed on a side of the card 110 that is away from the device chassis. This allows the card 110 to be fastened to the device motherboard 120 on a side away from the device chassis, which ensures that the card does not move or vibrate during production or transport.

In an example, the card fastener 150 comprises a first end portion 152 and a second end portion 154. The first end portion 152 is to removably couple with the plurality of hooks 160, also referred to as hooks 160, on the motherboard 120. A compressive pad 170 is present at the second end portion 154 of the card fastener 150. In various examples, the compressive pad comes in contact with the card 110 on assembly and may be made of materials such as rubber, foam, elastomer, and the like. The compressive pad 170 may deform or compress when the card fastener 150 comes in contact with the card 110 and thus prevent any damage to the card 110 when the card 110 is fastened to the motherboard 120 using the card fastener 150. In an example, the card fastener 150 may be made of spring wires.

In one example, the card fastener 150 comprises a holding portion 180. The holding portion 180 is manually deformable, which allows the first end portion 152 of the card fastener 150 to engage or disengage with the hooks 160. In an example, the card fastener 150 may be placed on the card 110 such that the compressive pad 170 comes in contact with the card 110 on the third side of the card 110. The holding portion 180 may be manually deformed to allow the first end portion 152 to engage with the hooks 160. Upon releasing the holding portion 180, the card fastener 150 may be engaged with the hooks 160 and thus fasten the card 110 to the motherboard 120. In another example, for releasing the card fastener 150 when it is engaged with the hooks 160, the holding portion 180 may be manually deformed to allow the first end portion 152 of the card fastener 150 to disengage from the hooks 160, which allows the card fastener 150 to be removed from the card 110.

In an example, the card 110 may be first connected to the motherboard 120 and then the card fastener 150 may be coupled to the card 110 and the motherboard 120. In another example, the card fastener 150 may be first disposed on the card 110 and then the card 110 along with the card fastener 150 may be connected to the slot 130.

The hooks 160 may be attached to the motherboard 120 using various methods such as by soldering, using an adhesive, and the like. In an example, the hooks 160 may be substantially U-shaped with the two arms of the U-shape being attached to the motherboard. The hooks 160 may be made of materials such as metals, plastic, and the like. In an example, the hooks 160 may be formed by bending a wire and passing it through a motherboard tray.

In an example, a pair of hooks 160 may be present to engage with the card fastener 150. The pair of hooks may engage with the first end portions 152 of the card fastener 150 and may be disposed on either side of the card 110 in a direction substantially perpendicular to the direction in which the length of the card 110 extends. In some examples, more than one pair of hooks 160 may be disposed on the motherboard 120. The pair of hooks 160 may be disposed on the motherboard 120 at a first distance from the slot 130 in a first direction, shown by arrow BA, the first direction being a direction in which a length of the card 110 is to extend. In an example, the hooks 160 may be disposed on a portion of the motherboard 120 that is away from the device chassis. In examples where there may be more than one pair of hooks 160, the hooks 160 may be placed along the first direction such that the hooks 160 are disposed along a straight line that is parallel to the direction in which the length of the card 110 extends. In another example, the hooks 160 may be disposed on one or more lines that are parallel to the direction in which the length of the card 110 extends such that the one or more lines are at a spaced-apart distance from each other.

The hooks 160 may be disposed on the motherboard 120 at a second distance from the card 110 in a second direction, shown by arrow BC, the second direction being substantially perpendicular to the direction in which the length of the card 110 extends. Thus, the pair of hooks 160 are at a spaced-apart distance from each other to allow a card 110 to pass between the hooks 160. In various examples, the hooks 160 may be placed at about 3-5 mm from the card 110 in the second direction. In other examples, the hooks 160 may be placed on the motherboard 120 away from connectors present on the motherboard 120 to prevent interference or shorting with the connectors. In an example, the pair of hooks 160 may be disposed on the motherboard 120 such that both the hooks 160 are at substantially the same first distance from the slot 130.

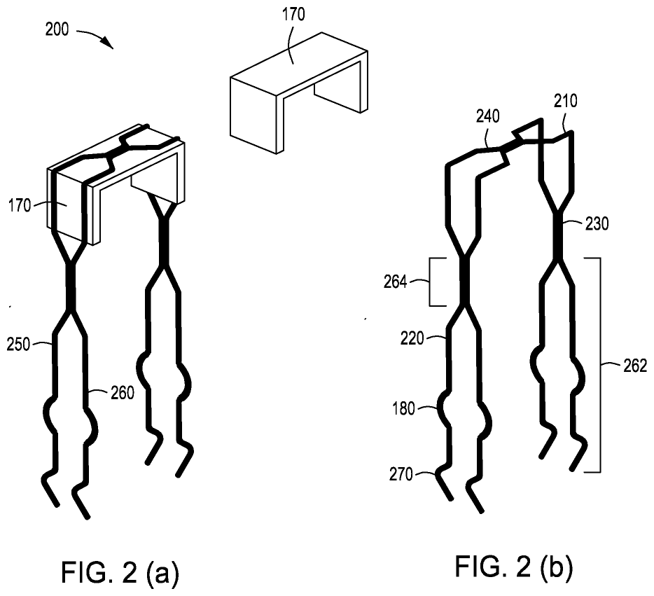

FIG. 2A illustrates an example card fastener 200 for fastening a card to a PCB, according to an example implementation of the present subject matter. FIG. 2B illustrates an exploded view of the card fastener 200 of FIG. 2A, according to an example implementation of the present subject matter. In one example, the card fastener 200 may correspond to the card fastener 150 discussed above. For ease of discussion, FIGS. 2A and 2B will be described together.

In an example, the card fastener 200 comprises a frame 210 comprising a first arm 220, a second arm 230, and an intermediate portion 240 joining the first arm 220 and the second arm 230. In an example, the first arm 220 and second arm 230 together may comprise the first end portion 152 of the card fastener 150 and the intermediate portion 240 may be the second end portion 154 of the card fastener 150. A compressive pad 170 may be attached to the intermediate portion 240. The compressive pad 170 is to come in contact with the card 110 on assembly. In various examples, the compressive pad 170 may be made from rubber, foam, elastomers, and other such materials and may be attached to the frame 210 using various methods, such as by an adhesive. When the compressive pad 170 is disposed on the card 110, the compressive pad 170 deforms, thus preventing damage to the card 110 because of the frame 210. The first arm 220 and the second arm 230 couple with hooks 160 on the device motherboard 120 to fasten the card 110 to the motherboard 120.

In an example, the frame 210 is substantially U-shaped. The intermediate portion 240 forms a base of the U-shape and the first arm 220 and the second arm 230 form the arms of the U-shape. The frame 210 may comprise a first wire element 250 and a second wire element 260 that are coupled together to form alternate spaced-apart portions 262 and connected portions 264 along a length of the frame 210. In an example, the frame 210 may comprise four spaced-apart portions 262 and three connected portions 264. In various examples, the frame 210 may comprise different number of spaced-apart portions 262 and connected portions 264.

In an example, the frame 210 may be made of spring wire, piano wire, and the like, to allow the wire elements 250 and 260 to be manually deformable and regain their original position upon release. In an example, the compressive pad 170 may be attached to a connected portion 264 and two spaced-apart portions 262 at the intermediate portion 240 of the frame 210. In an example, the compressive pad 170 may be attached using an adhesive.

The free ends of the first arm 220 and the second arm 230 comprise prongs 270, also referred to individually as prong 270, with a protrusion to couple to the hooks 160. In an example, free ends of the first arm 220 and the second arm 230 are on the spaced-apart portions 262 of the wire elements 250 and 260 such that the first arm 220 and the second arm 230 comprise two prongs each. In other examples, one prong 270 or more than two prongs 270 may be provided on the first arm 220 and the second arm 230.

A spaced-apart portion 262 of the first arm 220 and of the second arm 230 above the prongs 270 may each comprise a holding portion 180. In an example, the holding portion 180 may be formed by curved portions provided on each of the first wire element 250 and the second wire element 260. The holding portion 180 may be manually deformed to allow the first arm 220 and the second arm 230 to come close to each other and to allow the protrusion on the prong 270 to be clear of the hooks 160. When the holding portion 180 is released, the first arm 220 and the second arm 230 move apart and the prongs 270 may engage with the hooks 160, thus fastening the card 110 to the motherboard 120. To unfasten the card 110, the holding portion 180 may be manually deformed to allow the prongs 270 to disengage from the hooks 160.

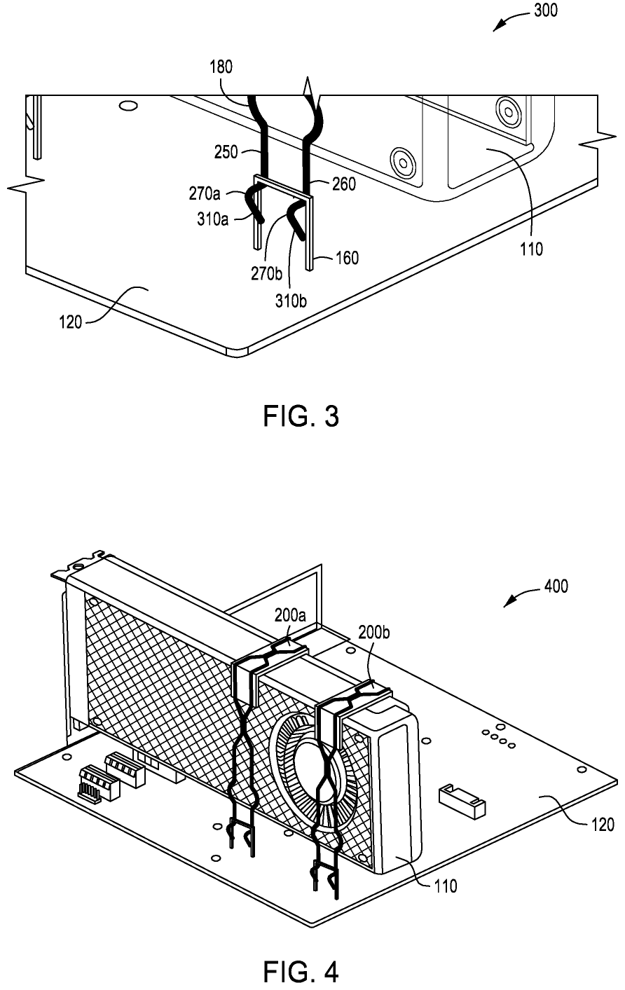

FIG. 3 illustrates an enlarged view of an example card fastener 200 coupled to a hook 160 on a PCB, according to an example implementation of the present subject matter. Card fastener 200 may be disposed on the card 110 and prongs 270 of the card fastener 200 may be coupled to the hook 160 that is attached to the motherboard 120. For this, prongs 270a and 270b on the first wire element 250 and the second wire element 260, respectively, comprise protrusions 310a and 310b. When the holding portion 180 of the first wire element 250 and the second wire element 260 are manually deformed, the protrusions 310a and 310b may be clear of the hook 160. The protrusions 310a and 310b may be together referred to as protrusions 310. When the holding portion 180 is released, the prongs 270a and 270b move towards the hook 160 allowing the protrusions 310 to lock in the hook 160. The holding portion 180 may be manually deformed when the protrusions 310 are locked, which allows the protrusions 310 to be released from the hook 160.

FIG. 4 illustrates another example assembly 400 of a card fastened on a PCB, according to an example implementation of the present subject matter. The assembly 400 comprises a card 110 attached to a motherboard 120 via slot 130. In an example, two card fasteners 200a and 200b are attached to the card 110. The card 110 may be long, for example 12 inches long, and hence one card fastener 200 may be insufficient to fasten the card 110 to the motherboard 120 to arrest vibration or movement of the card 110. The card fasteners 200a and 200b may be coupled to the card 110 along the first direction extending along the length of the card 110 at a spaced-apart distance from each other. In one example, card fastener 200b may be disposed closer to a side of the card that is away from the device chassis and fastener 200a may be disposed at a distance from the card fastener 200b. The card fasteners 200a and 200b may each be engaged to the motherboard 120 via a pair of hooks 160.

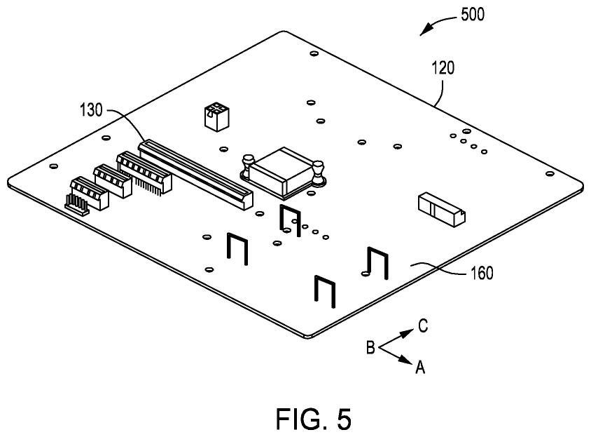

FIG. 5 illustrates an example printed circuit board 500 with hooks 160 for fastening a card, according to an example implementation of the present subject matter. In an example, the printed circuit board 500 may be a motherboard of a desktop computer, a gaming system, a workstation, or the like. The printed circuit board 500 may comprise a slot 130 to receive a card 110 (not shown here). In various examples, the printed circuit board 500 may comprise a plurality of slots 130 to receive a plurality of cards 110. The cards may be expansion cards, such as graphics cards, audio cards, memory cards, and the like.

The printed circuit board 500 may comprise a pair of hooks 160 provided on opposite sides of the slot 130 to allow the card 110 to be fastened to the printed circuit board 500. The number of pairs of hooks 160 provided on the printed circuit board 500 may correspond to the number of card fasteners 200 that may be used to fasten the card 110. In an example, the printed circuit board 500 may be provided with two pairs of hooks 160 and two card fasteners 200 may be used. Each card fastener 200 may be coupled to one pair of hooks 160. In another example, the number of pairs of hooks 160 may be more than the number of card fasteners 200 used to be able to fasten different sizes of cards at different times. Hence, at times, some pairs of hooks 160 may have no card fastener 200 engaged with them.

In an example, the pairs of hooks 160 may be provided on opposite sides of the slot 130 and at a spaced-apart distance from each other to allow the card 110 to pass between the hooks. The pairs of hooks 160 may be disposed on either side of the card 110 in a direction substantially perpendicular to the direction in which the length of the card 110 extends, shown by arrow BC. In various examples, each hook of the pairs of hooks may be placed 3-5 mm away from the card 110, the distance being measured in a direction substantially perpendicular to the direction in which the card 110 extends.

The pair of hooks 160 may be disposed at a first distance from the slot 130 in the first direction, shown by arrow BA, in which a length of the card 110 is to extend. In an example, the hooks 160 may be disposed on a portion of the motherboard 120 that is away from the device chassis. In examples where there may be more than one pairs of hooks 160, the hooks may be placed along the first direction BA such that the hooks 160 are disposed along a straight line that is parallel to the direction in which the length of the card extends. In another example, the hooks 160 may be disposed on one or more lines that are parallel to the direction in which the length of the card extends such that the one or more lines are at a distance from each other. In other examples, the hooks 160 may be placed on the motherboard 120 away from any connectors to prevent interference or shorting with the connectors. In an example, the pair of hooks 160 may be disposed on the motherboard 120 such that both the hooks 160 are at substantially the same first distance from the slot 130.

In various examples, the hooks 160 may be substantially U-shaped and may be soldered to the printed circuit board 500. In another example, the hooks 160 may be attached to the printed circuit board 500 using adhesives. The arms of the U-shape may be attached to the printed circuit board 500 with the bent portion of the U-shape protruding from the printed circuit board 500. In an example, the hooks 160 may be formed by bending a wire and passing it through a tray of the printed circuit board 500.

The preceding description has been presented to illustrate and describe examples of the principles described. This description is not intended to be exhaustive. Many modifications and variations are possible in light of the above teaching.

1. A card fastener comprising:
a frame comprising a first arm, a second arm, and an intermediate portion joining the first arm and the second arm; and
a compressive pad attached to the intermediate portion, wherein the first arm and the second arm are to couple to hooks on a printed circuit board and the compressive pad is to come in contact with a card.

2. The card fastener of claim 1, wherein the frame is substantially U-shaped with the intermediate portion forming a base of the U-shape and the first arm and the second arm forming arms of the U-shape.

3. The card fastener of claim 1, wherein free ends of the first arm and the second arm comprise a prong with a protrusion to couple to the hooks.

4. The card fastener of claim 1, wherein the frame comprises a first wire element and a second wire element coupled to each other to form alternate spaced-apart portions and connected portions along a length of the frame.

5. A printed circuit board comprising:
a slot to receive a card; and
a pair of hooks provided on opposite sides of the slot to allow the card to be fastened to the printed circuit board, wherein the pair of hooks is disposed at a first distance from the slot in a first direction in which a length of the card is to extend.

6. The printed circuit board of claim 5, wherein the pair of hooks have a substantially U-shape.

7. The printed circuit board of claim 5, wherein the pair of hooks is soldered to the printed circuit board.

8. The printed circuit board of claim 5, wherein hooks in the pair of hooks are spaced apart from each other to allow the card to pass between the hooks.

9. An assembly comprising:
a card connected to a motherboard;
a plurality of hooks attached to the motherboard; and
a card fastener removably disposed on the card, wherein a first end portion of the card fastener is removably coupled with the plurality of hooks to fasten the card to the motherboard.

10. The assembly of claim 9, wherein the card fastener comprises a compressive pad at a second end portion of the card fastener, wherein the second end portion is on a side opposite the first end portion.

11. The assembly of claim 10, wherein the compressive pad is in contact with the card.

12. The assembly of claim 9, wherein the card fastener is made of spring wires.

13. The assembly of claim 9, wherein the card fastener comprises a holding portion, wherein
the holding portion is manually deformable to allow the first end portion to engage with the plurality of hooks to fasten the card to the motherboard, and
the holding portion is manually deformable when the card fastener is engaged with the plurality of hooks to allow the first end portion to disengage from the plurality of hooks, to remove the card.

14. The assembly of claim 9, wherein a plurality of card fasteners is disposed on the card and coupled to the plurality of hooks on the motherboard.

15. The assembly of claim 9, wherein
the card is connected to the motherboard at a first side of the card and to a device chassis at a second side of the card, the second side being adjacent to the first side, and
the card fastener is disposed on the card on a third side of the card that is opposite to the first side, and wherein the card fastener is disposed closer to a fourth side of the card than to the second side, wherein the fourth side is opposite to the second side.
